(19) United States
(12) Patent Application Publication
(10) Pub. No.: US 2024/0158168 A1
(43) Pub. Date: May 16, 2024

(54) MOBILE TRANSPORT DEVICE AND MOBILE TRANSPORT SYSTEM INCLUDING THE SAME

(71) Applicant: SEMES CO., LTD., Chungcheongnam-do (KR)

(72) Inventors: Sangok PARK, Hwaseong-si (KR); Hoyoung LEE, Yongin-si (KR); Seungchan LEE, Hwaseong-si (KR)

(21) Appl. No.: 18/499,623

(22) Filed: Nov. 1, 2023

(30) Foreign Application Priority Data
Nov. 16, 2022 (KR) 10-2022-0153817

(51) Int. Cl. B65G 1/04; B66F 9/065

(52) U.S. Cl. CPC B65G 1/0471; B66F 9/065

(57) ABSTRACT

A mobile transport device includes: a pedestal having an upper surface on which one load among a plurality of types of loads requiring power for operation is selectively provided, and a lower surface including a docking groove; a docking table having a support upper surface for supporting the pedestal on which the plurality of types of loads are provided; and a mobile transport robot configured to transport the pedestal on which the plurality of types of loads are provided, by connecting the docking groove to a docking block provided on an upper surface thereof. The docking groove in the lower surface of the pedestal is complementarily connected to the docking block provided on an upper surface of the mobile transport robot, so that the load is electrically connected to the mobile transport robot. The mobile transport device increases transport efficiency and task efficiency.

### CROSS-REFERENCE TO RELATED APPLICATION

This application is based on and claims priority under 35 U.S.C. § 119 to Korean Patent Application No. 10-2022-0153817, filed on Nov. 16, 2022, in the Korean Intellectual Property Office, the disclosure of which is incorporated by reference herein in its entirety.

### BACKGROUND

### 1. Field

The disclosure relates to a mobile transport system, and more particularly, to a mobile transport system capable of loading equipment.

### 2. Description of the Related Art

In manufacturing facilities, automation of logistics is in progress. Logistics processing methods used in factories have started to employ mobile transport robots. Mobile transport robots are generally used for transporting loads, or mobile robots with a device capable of performing a specific task are used in mobile transport robots.

### SUMMARY

Provided are a mobile transport robot capable of selectively loading and transporting a load requiring power and control for operation, and a mobile transport system including the mobile transport robot.

The objects of the disclosure are not limited to the above object, and other objects that are not mentioned herein will be clearly understood by those of ordinary skill in the art from the following description.

Additional aspects will be set forth in part in the description which follows and, in part, will be apparent from the description, or may be learned by practice of the presented embodiments of the disclosure.

According to an aspect of the disclosure, a mobile transport device includes: a pedestal having an upper surface on which one load among a plurality of types of loads requiring power for operation is selectively provided, and a lower surface including a docking groove; a docking table having a support upper surface for supporting the pedestal on which the plurality of types of loads are provided; and a mobile transport robot configured to transport the pedestal on which the plurality of types of loads are provided, by connecting the docking groove to a docking block provided on an upper surface thereof, wherein the docking groove in the lower surface of the pedestal is complementarily connected to the docking block provided on an upper surface of the mobile transport robot, so that the load is electrically connected to the mobile transport robot.

In addition, according to an embodiment, the docking block may be configured to be raised or lowered.

In addition, according to an embodiment, the docking table may be configured so that an inside of the support upper surface is hollow by removing a portion of the support upper surface from one side of a circumference of the support upper surface toward the inside of the support upper surface.

In addition, according to an embodiment, a planar shape of the pedestal may be a rectangular shape having four corners, three of the four corners may be supported by the support upper surface, and only a portion of the remaining one corner may be supported by the support upper surface.

In addition, according to an embodiment, in order for the mobile transport robot to transport the pedestal on which the load is provided, the docking block may be raised and the docking block may be connected to the docking groove in the pedestal so that the mobile transport robot may be connected to the pedestal, and the docking block may be further raised to lift the pedestal on which the load is provided, from the support upper surface so that the docking table may be spaced apart from the pedestal.

In addition, according to an embodiment, the docking table may be spaced apart from the pedestal and the mobile transport robot may be moved.

In addition, according to an embodiment, a terminal may at least partially protrude from an upper surface of the docking block, and the terminal may be a communication terminal or a power terminal.

In addition, according to an embodiment, a recessed groove may be formed in the upper surface of the docking block, an elastic member may be provided in the recessed groove, and at least a portion of the terminal may be inserted into the recessed groove so that one end of the terminal may come into contact with one end of the elastic member.

In addition, according to an embodiment, one or more communication terminals may be provided on the docking block, and one or more power terminals may be provided on the docking block.

In addition, according to an embodiment, four docking blocks may be provided on an upper surface of the mobile transport robot, four docking grooves may be formed in the lower surface of the pedestal, the four docking blocks may be spaced apart from each other, the four docking grooves may be spaced apart from each other, and the docking blocks may be engaged with and complementarily connected to the docking grooves.

In addition, according to an embodiment, a planar shape of the docking blocks may be an L-shape and a planar shape of the docking grooves may be an L-shape, so that the docking blocks may be engaged with and complementarily connected to the docking grooves.

In addition, according to an embodiment, a cross-sectional shape of the docking blocks in a plane may be a rectangular shape and a cross-sectional shape of the docking grooves in a plane may be a rectangular shape, so that the docking blocks may be engaged with and complementarily connected to the docking grooves.

In addition, according to an embodiment, two power terminals and one communication terminal may be provided in two docking blocks among the four docking blocks.

According to another of the disclosure, a mobile transport system includes a mobile transport device including: a pedestal having an upper surface on which one load among a plurality of types of loads requiring power for operation is selectively provided, and a lower surface including a docking groove; a docking table having a support upper surface for supporting the pedestal on which the plurality of types of loads are provided, and configured so that an inside of the support upper surface is hollow by removing a portion of the support upper surface from one side of a circumference of the support upper surface toward the inside of the support upper surface; and a mobile transport robot configured to transport the pedestal on which one load among the plurality of types of loads is provided, by connecting the docking groove to a docking block provided on an upper surface thereof and configured to be raised or lowered, wherein the docking groove in the lower surface of the pedestal is complementarily connected to the docking block provided on an upper surface of the mobile transport robot, so that the one load among the plurality of types of loads is electrically connected to the mobile transport robot, and the mobile transport device is connected to a transport target load placed on the docking table and transports the transport target load.

In addition, according to an embodiment, the mobile transport device may be selectively moved to one docking table among a plurality of docking tables on which the plurality of types of loads are provided, and may be connected to the transport target load placed on the one docking table, and the mobile transport device may be selectively moved to one docking table among the plurality of docking tables on which the plurality of types of loads are not provided, and may load the transport target load on the one docking table.

In addition, according to an embodiment, the mobile transport device may transport the transport target load to a specific location where the transport target load is required, and the transport target load loaded on the mobile transport robot may be operated to perform a specific task.

In addition, according to an embodiment, a terminal may at least partially protrude from an upper surface of the docking block, the terminal may include a communication terminal or a power terminal, a recessed groove may be formed in the upper surface of the docking block, an elastic member may be provided in the recessed groove, and at least a portion of the terminal may be inserted into the recessed groove so that one end of the terminal may come into contact with one end of the elastic member.

In addition, according to an embodiment, four docking blocks may be provided on an upper surface of the mobile transport robot, four docking grooves may be formed in the lower surface of the pedestal, the four docking blocks may be spaced apart from each other, the four docking grooves may be spaced apart from each other, a planar shape of the docking blocks may be an L-shape, a planar shape of the docking grooves may be an L-shape, and the docking blocks may be engaged with and complementarily connected to the docking grooves.

In addition, according to an embodiment, two power terminals and one communication terminal may be provided in two docking blocks among the four docking blocks.

According to another aspect of the disclosure, a mobile transport device includes: a pedestal having an upper surface on which one load among a plurality of types of loads requiring power for operation is selectively provided, and a lower surface including a docking groove; a docking table having a support upper surface for supporting the pedestal on which the plurality of types of loads are provided, and configured so that an inside of the support upper surface is hollow by removing a portion of the support upper surface from one side of a circumference of the support upper surface toward the inside of the support upper surface; and a mobile transport robot configured to transport the pedestal on which the plurality of types of loads are provided, by connecting the docking groove to a docking block provided on an upper surface thereof, wherein the docking block is configured to be raised or lowered, a terminal at least partially protrudes from an upper surface of the docking block, the terminal being a communication terminal or a power terminal,
a recessed groove is formed in the upper surface of the docking block, an elastic member is provided in the recessed groove,
at least a portion of the terminal is inserted into the recessed groove so that one end of the terminal comes into contact with one end of the elastic member, a planar shape of the docking block is an L-shape, four docking blocks are provided on the upper surface of the mobile transport robot and are spaced apart from each other,
two docking blocks among the four docking blocks each include two power terminals and one communication terminal, a planar shape of the docking groove is an L-shape, four docking grooves are formed in the lower surface of the pedestal to be spaced apart from each other, and the docking groove in the lower surface of the pedestal is complementarily connected to the docking block provided on an upper surface of the mobile transport robot, so that the load is electrically connected to the mobile transport robot.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view illustrating a mobile transport device according to an embodiment;

FIG. 2 is a perspective view illustrating a mobile transport robot of a mobile transport device, according to an embodiment;

FIG. 3A is an enlarged view of region A of FIG. 2, which is a portion of the mobile transport robot of the mobile transport device illustrated in FIG. 2, according to an embodiment;

FIG. 3B is a cross-sectional view taken along line A-A′ of FIG. 3A;

FIG. 4 is a perspective view illustrating a portion of a mobile transport device, according to an embodiment;

FIG. 5 is a perspective view illustrating a mobile transport device according to an embodiment;

FIG. 6 is a perspective view illustrating a mobile transport robot, which is a portion of a mobile transport device, according to an embodiment;

FIG. 7A is a perspective view illustrating a mobile transport robot of a mobile transport device, according to an embodiment;

FIG. 7B is a perspective view illustrating a pedestal on which a load is provided in a mobile transport device, according to an embodiment;

FIG. 8A is a diagram for describing a mobile transport system including a mobile transport device, according to an embodiment;

FIG. 8B is a diagram for describing a mobile transport system including a mobile transport device, according to an embodiment; and

FIG. 8C is a diagram for describing a mobile transport system including a mobile transport device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. The same elements in the drawings are denoted by the same reference numerals, and redundant descriptions thereof are omitted.

It will be understood that when a portion is referred to as being “connected to” another portion, it may be “directly connected to” the other portion or “indirectly connected to” the other portion with intervening members therebetween. It will be understood that the terms “comprise,” “include,” or “have” as used herein specify the presence of stated elements, but do not preclude the presence or addition of one or more other elements.

Unless defined otherwise, all terms including technical or scientific terms as used herein have the same meaning as commonly understood by those of ordinary skill in the art. It will be understood that terms, such as those defined in commonly used dictionaries, should be interpreted as having a meaning that is consistent with their meaning in the context of the relevant art and will not be interpreted in an idealized or overly formal sense unless expressly so defined herein.

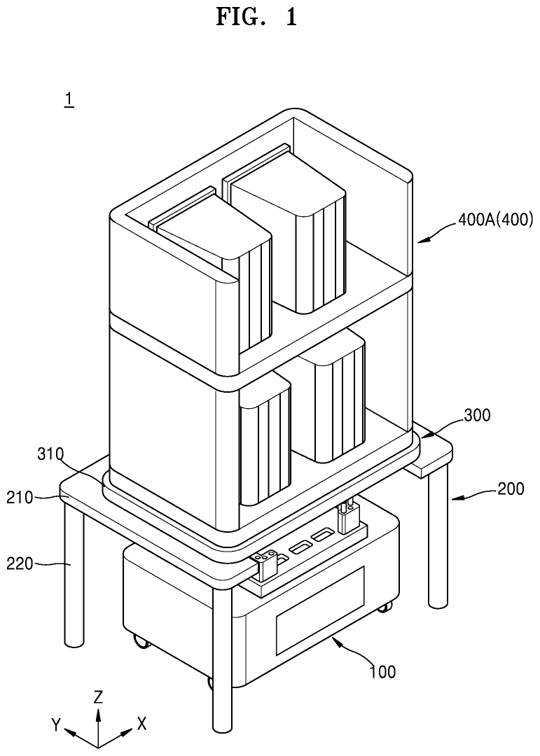

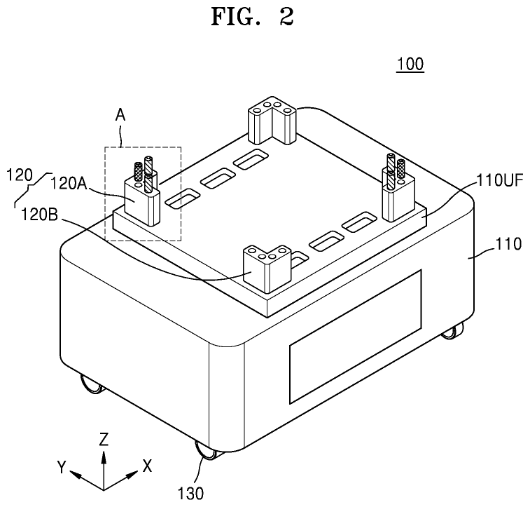

FIG. 1 is a perspective view illustrating a mobile transport device 1 according to an embodiment. FIG. 2 is a perspective view illustrating a mobile transport robot 100 of the mobile transport device 1, according to an embodiment.

Referring to FIGS. 1 and 2, the mobile transport device 1 according to an embodiment may include the mobile transport robot 100, a pedestal 300 configured to be connectable to the mobile transport robot 100, a load 400 provided on the pedestal 300, and a docking table 200 on which the pedestal 300 is placed

The mobile transport robot 100 may include a plurality of wheels 140 thereunder. The wheels 140 may be driving wheels to which driving force is applied, or may be support wheels to which no driving force is applied. At least one of the wheels 140 may be a steering wheel configured to maintain or change the traveling direction of the mobile transport robot 100. Alternatively, the wheels 140 may be non-steerable wheels. Accordingly, at least one of the wheels 140 may be a steerable wheel to which driving force is applied.

The mobile transport robot 100 may include the wheels 140. As illustrated in FIGS. 1 and 2, a portion of a circular wheel may be exposed on the inner side of the lower surface of the mobile transport robot 100. The mobile transport robot 100 may include three or more wheels 140. For example, the mobile transport robot 100 may include four wheels 140. When the planar shape of the mobile transport robot 100 is close to a rectangular shape, the four wheels 140 may be respectively located inside four vertices of the rectangular shape so that the mobile transport robot 100 travels stably.

The mobile transport robot 100 may transmit and receive an external electric signal in a wired or wireless manner. The external electric signal may include information about a moving method or a location for moving the mobile transport robot 100. The mobile transport robot 100 may transmit and receive an electric signal for operating the load 400 to be described below. The mobile transport robot 100 may include a battery configured to supply power to the mobile transport robot 100. The mobile transport robot 100 may include a controller configured to control the mobile transport robot 100. However, the configuration of the mobile transport robot 100 is not limited by the description of the present specification.

A protruding upper surface 110UF may be provided on the upper surface of the mobile transport robot 100. The protruding upper surface 110UF may have a level difference from the upper surface of the mobile transport robot 100 in the vertical direction.

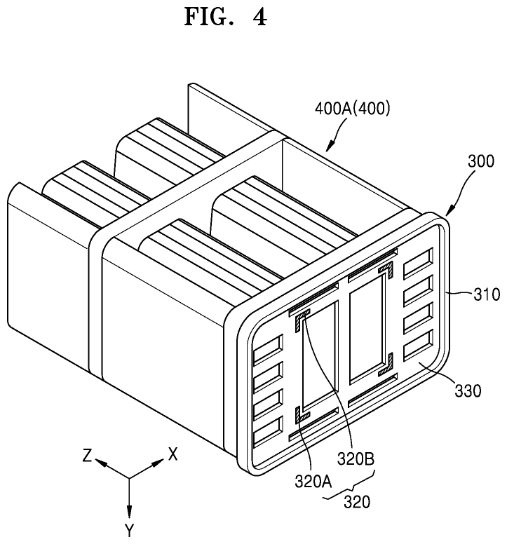

The mobile transport robot 100 may include a body portion 110. The protruding upper surface 110UF may be provided on the upper surface of the body portion 110. Docking blocks 120 configured to be connectable to the pedestal 300 may be provided on the protruding upper surface 110UF of the mobile transport robot 100. The docking blocks 120 may be respectively connected to docking grooves 320 in the pedestal 300, which is to be described with reference to FIG. 4. The docking grooves 320 and the docking blocks 120 may be connected to each other to enable the mobile transport robot 100 to supply power to the load 400. The docking grooves 320 and the docking blocks 120 may be connected to each other to enable the load 400 to transmit and receive an electric signal through the mobile transport robot 100.

The docking blocks 120 may include a connection bracket 120A having terminals 130 to be described with reference to FIG. 4 and a support bracket 120B having no terminals 130. At least one of the docking blocks 120 includes the connection bracket 120A. The docking blocks 120 other than the connection bracket 120A may be the support bracket 120B.

Because the connection bracket 120A has the terminals 130, the connection bracket 120A may be electrically connected to the pedestal 300 and the load 400. At the same time, the connection bracket 120A may support the pedestal 300. Because the support bracket 120B has no terminals 130, the support bracket 120B may not be electrically connected to the pedestal 300 and the load 400, and the connection bracket 120A may support the pedestal 300.

The pedestal 300 may support the load 400 and may be disposed on the docking table 200. A detailed description of the pedestal 300 will be described below.

The docking table 200 may include a support upper surface 210 configured to support the pedestal 300, and support legs 220 configured to support the support upper surface 210. The support legs 220 are configured to withstand the weight applied to the support upper surface 210. The support upper surface 210 may have a flat upper portion so that the pedestal 300 is placed thereon.

While supporting the pedestal 300, the support upper surface 210 has to have a space in which the docking blocks 120 of the mobile transport robot 100 are connected to the docking grooves 320 in the lower surface of the pedestal 300 to be described below. Therefore, the support upper surface 210 may have a shape in which a central portion thereof is hollow.

In order for the mobile transport robot 100 to transport the pedestal 300 including the load 400 after the docking blocks 120 of the mobile transport robot 100 are connected to the docking grooves 320 in the lower surface of the pedestal 300, the support upper surface 210 of the docking table 200 may have a shape in which one side thereof is open. The support upper surface 210 may have a shape in which the central portion thereof is hollow and one side thereof is open.

In an embodiment, the horizontal and vertical sizes of the support upper surface 210 may be greater than the horizontal and vertical sizes of the pedestal 300, respectively. As described above, the support upper surface 210 may have a shape in which the central portion thereof is hollow and one side thereof is open. In other words, the planar shape of the support upper surface 210 may have a horseshoe shape. The pedestal 300 on which the load 400 is provided may be connected to the mobile transport robot 100 and exited through the open portion of the horseshoe-shaped support upper surface 210.

The load 400 may be disposed on the pedestal 300, or may be fixedly connected to the pedestal 300. The load 400 may be an active load 400 requiring power. In addition, the load 400 may require external control. The load 400 may include a variety of equipment. The load 400 may be supplied with power from the mobile transport robot 100, or may be supplied with power from a separate power source or a built-in power source. The load 400 may be moved to a specific place by the mobile transport device 1. The load 400, which is loaded on the mobile transport device 1, may be operated to perform a specific task.

As illustrated in FIG. 1, the mobile transport device 1 according to an embodiment may transport the load 400. In an embodiment, a first load 400A may include one or more overhead hoist transport front opening universal pods (OHT FOUPs).

In order to increase the efficiency of semiconductor manufacturing processes, a method of improving the semiconductor manufacturing processes and a technique for quickly and efficiently transporting products (e.g., substrates) between manufacturing facilities have been introduced. As a representative example, an OHT system for transporting products along a path installed on a ceiling of a semiconductor manufacturing plant is applied. In general, the OHT system includes a rail constituting a traveling path, and a transport vehicle configured to transport products while traveling along the rail. In addition, when it is necessary to store products during transport between semiconductor manufacturing facilities, a storage system for storing the products may be provided. The substrates may be transported in a state of being stored in the OHT FOUP, which is a container capable of accommodating a plurality of substrates. The container, which accommodates the substrates, may be transported by the transport vehicle.

The mobile transport device 1 according to an embodiment may include the first load 400A including one or more OHT FOUPs on the pedestal 300. As described above, the OHT system may load and transport the OHT FOUP between the manufacturing facilities through the rail installed on the ceiling. Even the mobile transport device 1 according to an embodiment may load the first load 400A including the OHT FOUP on the mobile transport robot 100, and may transport the first load 400A to a specific destination. Therefore, the mobile transport device 1 may supplement or replace the OHT system.

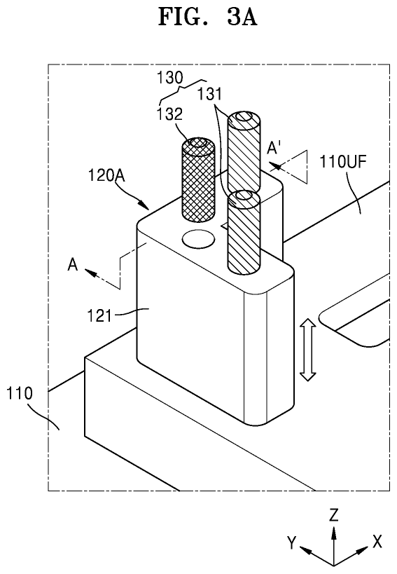

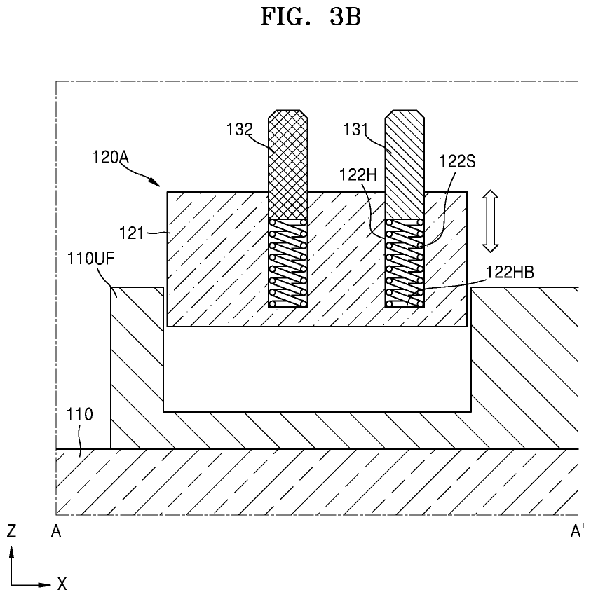

FIG. 3A is an enlarged view of region A of FIG. 2, which is a portion of the mobile transport robot 100 of the mobile transport device 1 illustrated in FIG. 2, according to an embodiment. FIG. 3B is a cross-sectional view taken along line A-A′ of FIG. 3A.

Referring to FIGS. 3A and 3B, the docking blocks 120 may be provided on the protruding upper surface 110UF. The docking blocks 120 may include the connection bracket 120A. The connection bracket 120A may include a bracket body 121, a terminal groove 122H recessed in the upper surface of the bracket body 121, and terminals 130. The terminals 130 may include a power terminal 131 and a communication terminal 132.

The power terminal 131 may supply power to the load 400 provided on the upper surface of the pedestal 300 connected to the mobile transport robot 100. That is, power may be supplied from the mobile transport robot 100 to the load 400. The load 400 may be operated by the power. Therefore, the load 400 may be operated by the power to perform the function of the load 400, and the mobile transport robot 100 may move to a place where the load 400 is required.

The mobile transport robot 100 may include a separate connector (not illustrated) so as to be charged or supplied with power. Alternatively, a power charging device may be provided on the pedestal 300 disposed on the docking table 200, and the power terminal 131 may be connected to a docking groove 320A to be described with reference to FIG. 4, so that the mobile transport robot 100 is charged by the power charging device.

The communication terminal 132 may transmit an electric signal to the load 400 provided on the upper surface of the pedestal 300 connected to the mobile transport robot 100. Alternatively, the communication terminal 132 may receive an electric signal from the load 400 provided on the upper surface of the pedestal 300 connected to the mobile transport robot 100. The load 400 may be supplied with power by the power terminal 131, may be operated by the power, and may be controlled by the mobile transport robot 100 through the communication terminal 132.

The mobile transport robot 100 may include a separate controller, or may be controlled through wireless communication or the like by a separate external controller. Therefore, even when the load 400 does not include a separate communication device or controller, the operation of the load 400 may be controlled by the mobile transport robot 100 when the load 400 is connected through the communication terminal 132 of the mobile transport robot 100.

The connection bracket 120A may include the terminal groove 122H recessed inward from the upper surface of the connection bracket 120A. The terminal groove 122H may have a shape capable of complementary engagement with the side surfaces of the terminals 130. In an embodiment, when the terminals 130 have a cylindrical shape, the terminal groove 122H may be formed in the upper surface of the connection bracket 120A so that the cylindrical shape meeting the specification of the terminals 130 is inserted thereinto.

An elastic member 122S may be provided at the other end opposite to the upper end of each of the terminals 130. The elastic member 122S may be provided on a groove bottom surface 122HB, which is the bottom surface of the terminal groove 122H. In an embodiment, the elastic member 122S may be a spring. The elastic member 122S may support the terminals 130 on the groove bottom surface 122HB, or may provide elasticity to the motion of the terminals 130. When the elastic member 122S is a spring, an electric wire (not illustrated) connected to the terminal and the power device or the communication device in the mobile transport robot 100 through the center of the spring may be provided.

When the connection bracket 120A including the terminals 130 is connected to the docking groove 320A to be described below, the terminals 130 may be pressed due to an error during connection. Due to the elastic member 122S provided on the lower surface of each of the terminals 130, the terminals 130 may be smoothly connected to the docking groove 320A.

The connection bracket 120A may be driven up and down, based on the Z-axis direction. In the drawings, the direction where the Z-axis direction is directed refers to ‘up,’ and the opposite direction refers to ‘down.’ Similar to the connection bracket 120A, the support bracket 120B described with reference to FIG. 2 may be driven up and down, based on the Z-axis direction.

The docking blocks 120 may be raised or lowered by actuators (not illustrated) in the mobile transport robot 100. The docking blocks 120 are connected to the docking grooves 320 formed in the lower surface of the pedestal 300 to be described below. When the docking blocks 120 are connected to the docking grooves 320 and are raised, the pedestal 300 including the docking grooves 320 may be raised. Alternatively, when the docking blocks 120 are connected to the docking grooves 320 and are lowered, the pedestal 300 including the docking grooves 320 may be lowered.

When the pedestal 300 on which the load 400 is provided is raised because the docking blocks 120 connected to the docking grooves 320 is raised, the load 400 on the mobile transport robot 100 may be raised. In contrast, when the pedestal 300 on which the load 400 is provided is lowered because the docking blocks 120 connected to the docking grooves 320 is lowered, the load 400 on the mobile transport robot 100 may be lowered.

The mobile transport robot 100 may lift the pedestal 300 on which the load 400 is provided in a state where the pedestal 300 is located on the support upper surface 210, which is the upper surface of the docking table 200. When the pedestal 300 on which the load 400 is provided is lifted, the pedestal 300 may be spaced apart from the support upper surface 210, which is the upper surface of the docking table 200, and the mobile transport robot 100 may move. When the mobile transport robot 100 loads and moves the load 400, the pedestal 300 on which the load 400 is provided may be moved from the docking table 200.

FIG. 4 is a perspective view illustrating a portion of the mobile transport device 1, according to an embodiment.

Referring to FIG. 4, the pedestal 300 may be located on the lower surface of the load 400. The pedestal 300 may include a support layer 310 protruding downward along the outer circumference. The docking grooves 320 may be formed in a lower surface 330 of the pedestal 300. The docking grooves 320 may include a first docking groove 320A connected to the connection bracket 120A and a second docking groove 320B connected to the support bracket 120B.

Referring to FIGS. 2 and 4, one or more docking blocks 120 may be provided on the protruding upper surface 110UF. In an embodiment, four docking blocks 120 may be provided on the protruding upper surface 110UF. The docking blocks 120 may be located inside the vertices of the rectangular shape, which is an embodiment of the planar shape of the protruding upper surface 110UF. The docking blocks 120 may each have an L-shape, based on a plane.

The docking blocks 120 each having an L-shape may be configured so that the outer side of the bent protruding portion is directed toward each vertex of the rectangular shape, which is an embodiment of the planar shape of the protruding upper surface 110UF. As illustrated in FIG. 2, the docking blocks 120 may be provided in an L-shape extending from the bent protruding portion in the X-axis direction and the Y-axis direction. Through the shape and arrangement of the docking blocks 120 as described above, the docking blocks 120 may more stably support the pedestal 300 located on the docking blocks 120.

Because the first docking groove 320A has to be connected to the terminals 130 of the connection bracket 120A, the first docking groove 320A may include connection holes (not illustrated) through which the terminals 130 are inserted and electrically connected. Because the connection holes have be connected to the terminals 130 of the connection bracket 120A, the connection holes may be complementarily connected to the terminals 130. In an embodiment, because the terminals 130 protruding from the connection bracket 120A each have a cylindrical shape and the connection holes each have a shape surrounding the cylindrical side surfaces of the terminals 130, the connection holes may be complementarily connected to the terminals 130.

The docking grooves 320 may be formed to have no level difference from the lower surface 330 of the pedestal 300 in the vertical direction. Alternatively, the docking grooves 320 may be formed to have a level difference from the lower surface 330 of the pedestal 300 in the vertical direction. In an embodiment, the docking grooves 320 may have a shape recessed inward from the lower surface 330 of the pedestal 300.

When the docking grooves 320 have no level difference from the lower surface 330 of the pedestal 300 in the vertical direction, the docking grooves 320 may easily come into contact with the docking blocks 120. When the docking grooves 320 have a level difference from the lower surface 330 of the pedestal 300 in the vertical direction, the recessed side surfaces of the docking grooves 320 and the side surfaces of the docking blocks 120 come into contact with each other, and thus, the docking grooves 320 may be more stably connected to the docking blocks 120.

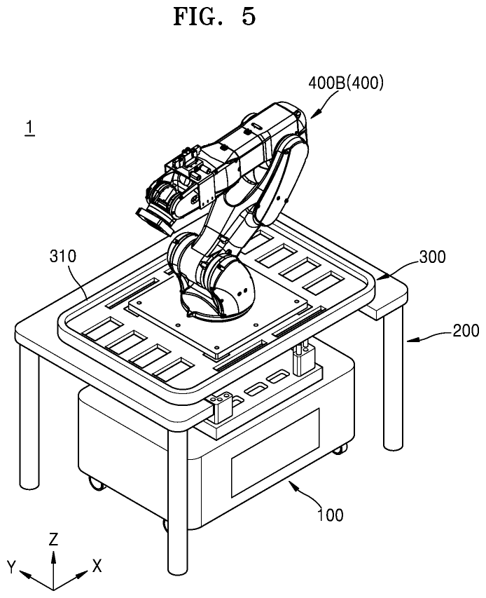

FIG. 5 is a perspective view illustrating a mobile transport device 1 according to an embodiment.

Referring to FIG. 5, a load 400 may be a second load 400B provided with a robot arm, instead of the first load 400A provided with the OHT FOUP. The robot arm requires power and an electric signal for control. Terminals 130 of a mobile transport robot 100 may be connected to a pedestal 300 to supply power to the robot arm and transmit an electric signal for control.

For example, the second load 400B provided with the robot arm may be moved to a location requiring the robot arm by the mobile transport robot 100, and the robot arm may be controlled to perform an operation required at the corresponding location.

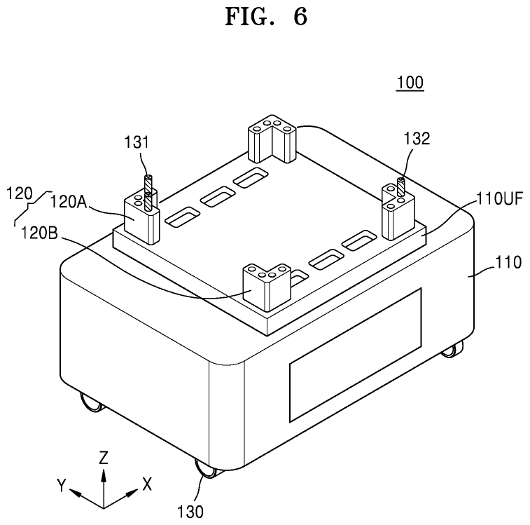

FIG. 6 is a perspective view illustrating the mobile transport robot 100, which is a portion of the mobile transport device 1, according to an embodiment. The redundant descriptions as provided above are omitted.

Referring to FIG. 6, a connection bracket 120A may include terminals 130. As illustrated in FIG. 2, one connection bracket 120A may include two power terminals 131 and one communication terminal 132. One connection bracket 120A may include one or more power terminals 131 or one or more communication terminals 132.

In an embodiment, as illustrated in FIG. 6, the connection bracket 120A located at the left upper end may include only two power terminals 131 in the X-Y plane. The connection bracket 120A located at the right lower end may have only one communication terminal 132. As described above, the connection bracket 120A and a support bracket 120B may be provided as necessary. Similarly, the connection bracket 120A may include the power terminal 131 and the communication terminal 132 as necessary.

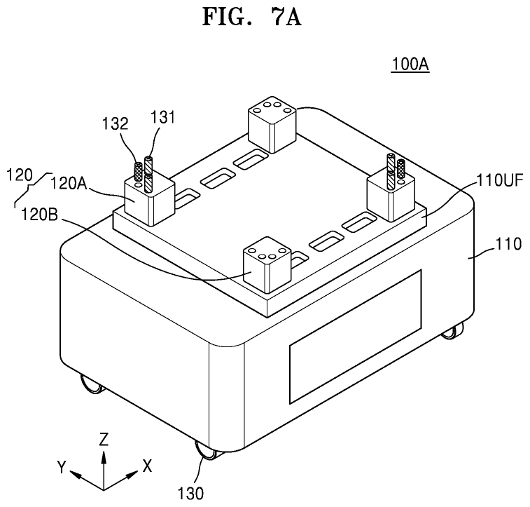

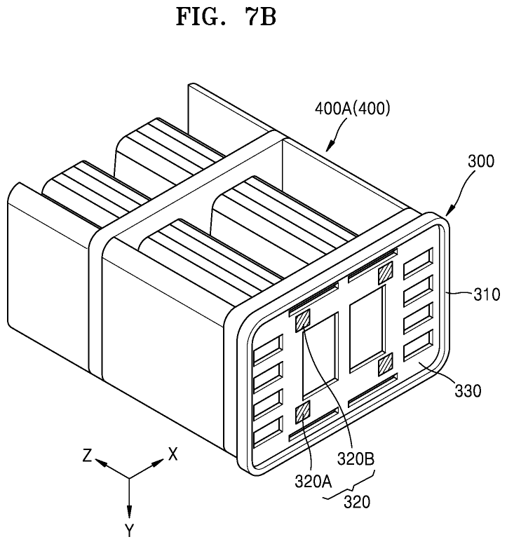

FIG. 7A is a perspective view illustrating a mobile transport robot 100A of the mobile transport device 1, according to an embodiment. FIG. 7B is a perspective view illustrating a pedestal 300 with a load 400, which is included in the mobile transport device 1, according to an embodiment. The redundant descriptions as provided above are omitted.

Referring to FIGS. 7A and 7B, docking blocks 120 may each have a rectangular shape in the X-Y plane. That is, the docking blocks 120 may each have a square pillar shape. The docking grooves 320 connected to the docking blocks 120 may each have a rectangular shape with respect to the plane of the pedestal 300. In an embodiment, the docking blocks 120 may each have a square shape in the X-Y plane.

The docking blocks 120 may include terminals 130. The terminals 130 may include a power terminal 130A and a communication terminal 130B. In an embodiment, two power terminals 130A and one communication terminal 130B may be provided in connection brackets 120A located at the left upper end and the right lower end in the X-Y plane.

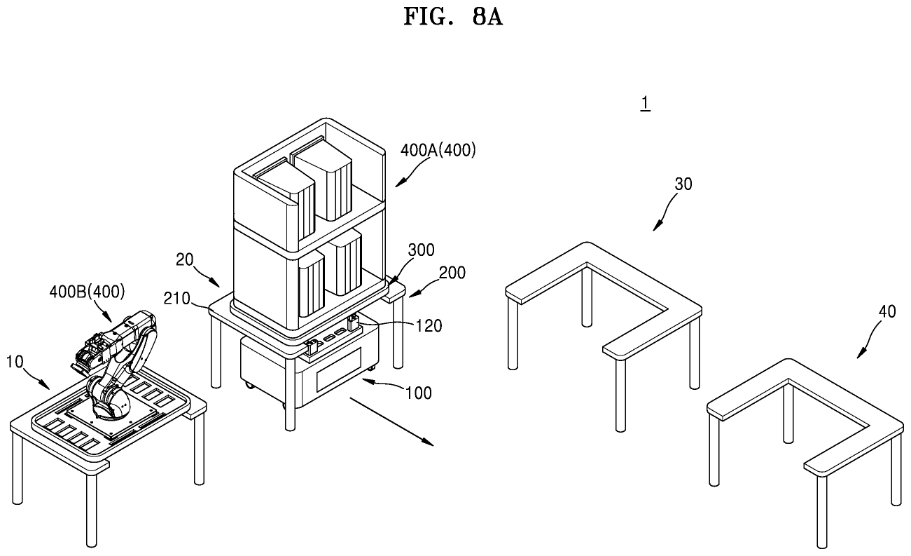

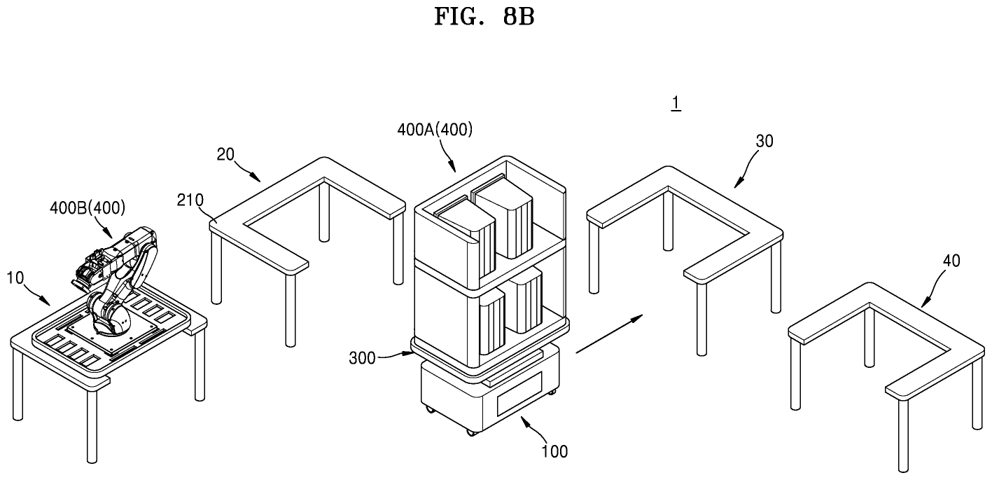

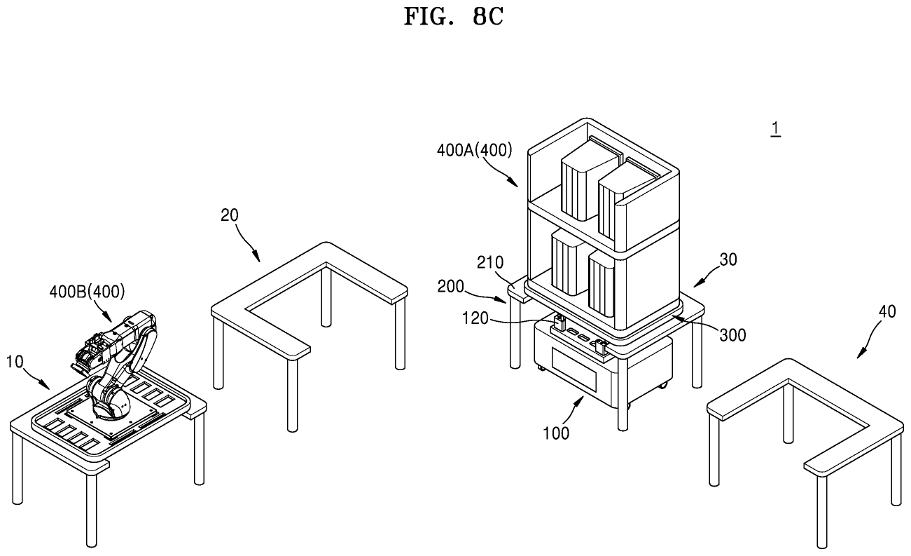

FIG. 8A is a diagram for describing a mobile transport system including a mobile transport device 1, according to an embodiment. FIG. 8B is a diagram for describing a mobile transport system including a mobile transport device 1, according to an embodiment. FIG. 8C is a diagram for describing a mobile transport system including a mobile transport device 1, according to an embodiment. The redundant descriptions as provided above are omitted.

The mobile transport device 1 may transport a load 400 located on a docking table 200 to another docking table 200, or the mobile transport device 1 with the load 400 loaded thereon may move to a specific target location.

A docking table 200 disposed at a specific location may be referred to as a first docking table 10. A docking table 200 disposed at a specific location different from that of the first docking table 10 may be referred to as a second docking table 20. A docking table 200 disposed at a specific location different from those of the first docking table 10 and the second docking table 20 may be referred to as a third docking table 30. A docking table 200 disposed at a specific location different from those of the first docking table 10, the second docking table 20, and the third docking table 30 may be referred to as a fourth docking table 40. For convenience of illustration and explanation, a case where the first to fourth docking tables 10, 20, 30, and 40 are arranged close to each other will be described as an example.

A first load 400A may be provided on the pedestal 300 and loaded on the second docking table 20. A second load 400B may be provided on the pedestal 300 and loaded on the first docking table 10. The mobile transport robot 100 may transport the required load 400, for example, the first load 400A as illustrated in FIG. 8A. As described above, the mobile transport robot 100 may be connected to docking grooves 320 formed in the lower surface of the pedestal 300 through docking blocks 120. As the docking blocks 120 are raised, the support upper surface 210 of the docking table 200 may be spaced apart from the pedestal 300. The load 400 to be transported by the mobile transport robot 100 may be referred to as a transport target load.

When the support upper surface 210 is spaced apart from the pedestal 300 and the first load 400A is loaded on the mobile transport robot 100, the mobile transport robot 100 may start moving. The mobile transport robot 100 may move the load 400 to a location where the load 400 is to be moved. A path along which the mobile transport robot 100 moves may be controlled by an external control device, or may be determined by a controller in the mobile transport robot 100.

A case where the first load 400A is transported to the third docking table 30 will be described as an example. The mobile transport robot 100 is located in the third docking table 30 so that the pedestal 300 provided at the lower end of the first load 400A is placed on the support upper surface 210 of the third docking table 30. When the docking blocks 120 are lowered, the pedestal 300 is placed on the support upper surface 210 of the third docking table 30. Accordingly, the first load 400A is loaded on the third docking table 30. When the docking blocks 120 is continuously lowered, the connection between the docking blocks 120 and the docking grooves 320 in the pedestal 300 is released. Through this process, the mobile transport device 1 may move the load 400 from a specific location to another location.

The case of moving the load from the docking table to the docking table has been described as an example with reference to FIGS. 8A to 8C. In addition to this, in the mobile transport device 1 and the mobile transport system including the same, according to an embodiment, the mobile transport device 1 may transport the load 400 to a specific location. The mobile transport robot 100 may supply power to the load 400 moved to the specific location, and may control the load 400 to operate. Through the mobile transport system, the specific load 400 is moved to a location where the load 400 is required, and the load 400 is operated to perform processing, enabling more flexible and efficient processing.

According to the disclosure, through the mobile transport system that selectively loads, on the transport robot, the active load that is operated by power, the active load is not fixed to the transport robot and may be selectively transported as necessary. Accordingly, the transport efficiency of the load may be increased. In addition, the work efficiency may be increased because the mobile transport robot transports the active load to a place where the active load is required and the active load operates on the mobile transport robot to perform a required task.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A mobile transport device comprising:
a pedestal having an upper surface on which one load among a plurality of types of loads requiring power for operation is selectively provided, and a lower surface including a docking groove;
a docking table having a support upper surface for supporting the pedestal on which the plurality of types of loads are provided; and
a mobile transport robot configured to transport the pedestal on which the plurality of types of loads are provided, by connecting the docking groove to a docking block provided on an upper surface of the mobile transport robot,
wherein the docking groove in the lower surface of the pedestal is complementarily connected to the docking block provided on an upper surface of the mobile transport robot, so that the load is electrically connected to the mobile transport robot.

2. The mobile transport device of claim 1, wherein the docking block is configured to be raised or lowered.

3. The mobile transport device of claim 2, wherein the docking table is configured so that an inside of the support upper surface is hollow by removing a portion of the support upper surface from one side of a circumference of the support upper surface toward the inside of the support upper surface.

4. The mobile transport device of claim 3, wherein a planar shape of the pedestal is a rectangular shape having four corners,
three of the four corners are supported by the support upper surface, and
only a portion of the remaining one corner is supported by the support upper surface.

5. The mobile transport device of claim 3, wherein, in order for the mobile transport robot to transport the pedestal on which the load is provided,
the docking block is raised and the docking block is connected to the docking groove in the pedestal so that the mobile transport robot is connected to the pedestal, and
the docking block is further raised to lift the pedestal on which the load is provided, from the support upper surface so that the docking table is spaced apart from the pedestal.

6. The mobile transport device of claim 5, wherein the docking table is spaced apart from the pedestal and the mobile transport robot is moved.

7. The mobile transport device of claim 5, wherein a terminal at least partially protrudes from an upper surface of the docking block, and
the terminal is a communication terminal or a power terminal.

8. The mobile transport device of claim 7, wherein a recessed groove is formed in the upper surface of the docking block,
an elastic member is provided in the recessed groove, and
at least a portion of the terminal is inserted into the recessed groove so that one end of the terminal comes into contact with one end of the elastic member.

9. The mobile transport device of claim 7, wherein one or more communication terminals are provided on the docking block, and
one or more power terminals are provided on the docking block.

10. The mobile transport device of claim 7, wherein four docking blocks are provided on an upper surface of the mobile transport robot,
four docking grooves are formed in the lower surface of the pedestal,
the four docking blocks are spaced apart from each other,
the four docking grooves are spaced apart from each other, and
the docking blocks are engaged with and complementarily connected to the docking grooves.

11. The mobile transport device of claim 10, wherein a planar shape of the docking blocks is an L-shape and a planar shape of the docking grooves is an L-shape so that the docking blocks are engaged with and complementarily connected to the docking grooves.

12. The mobile transport device of claim 10, wherein a cross-sectional shape of the docking blocks in a plane is a rectangular shape and a cross-sectional shape of the docking grooves in a plane is a rectangular shape so that the docking blocks are engaged with and complementarily connected to the docking grooves.

13. The mobile transport device of claim 10, wherein two power terminals and one communication terminal are provided in two docking blocks among the four docking blocks.

14. A mobile transport system comprising a mobile transport device comprising:
a pedestal having an upper surface on which one load among a plurality of types of loads requiring power for operation is selectively provided, and a lower surface including a docking groove;
a docking table having a support upper surface for supporting the pedestal on which the plurality of types of loads are provided, and configured so that an inside of the support upper surface is hollow by removing a portion of the support upper surface from one side of a circumference of the support upper surface toward the inside of the support upper surface; and
a mobile transport robot configured to transport the pedestal on which one load among the plurality of types of loads is provided, by connecting the docking groove to a docking block provided on an upper surface thereof and configured to be raised or lowered,
wherein the docking groove in the lower surface of the pedestal is complementarily connected to the docking block provided on an upper surface of the mobile transport robot, so that the one load among the plurality of types of loads is electrically connected to the mobile transport robot, and
the mobile transport device is connected to a transport target load placed on the docking table and transports the transport target load.

15. The mobile transport system of claim 14, wherein the mobile transport device is selectively moved to one docking table among a plurality of docking tables on which the plurality of types of loads are provided, and is connected to the transport target load placed on the one docking table, and
the mobile transport device is selectively moved to one docking table among the plurality of docking tables on which the plurality of types of loads are not provided, and loads the transport target load on the one docking table.

16. The mobile transport system of claim 14, wherein the mobile transport device transports the transport target load to a specific location where the transport target load is required, and the transport target load loaded on the mobile transport robot is operated to perform a specific task.

17. The mobile transport system of claim 14, wherein a terminal at least partially protrudes from an upper surface of the docking block,
the terminal comprises a communication terminal or a power terminal,
a recessed groove is formed in the upper surface of the docking block,
an elastic member is provided in the recessed groove, and
at least a portion of the terminal is inserted into the recessed groove so that one end of the terminal comes into contact with one end of the elastic member.

18. The mobile transport system of claim 17, wherein four docking blocks are provided on an upper surface of the mobile transport robot,
four docking grooves are formed in the lower surface of the pedestal,
the four docking blocks are spaced apart from each other,
the four docking grooves are spaced apart from each other,
a planar shape of the docking blocks is an L-shape,
a planar shape of the docking grooves is an L-shape, and
the docking blocks are engaged with and complementarily connected to the docking grooves.

19. The mobile transport system of claim 18, wherein two power terminals and one communication terminal are provided in two docking blocks among the four docking blocks.

20. A mobile transport device comprising:
a pedestal having an upper surface on which one load among a plurality of types of loads requiring power for operation is selectively provided, and a lower surface including a docking groove;
a docking table having a support upper surface for supporting the pedestal on which the plurality of types of loads are provided, and configured so that an inside of the support upper surface is hollow by removing a portion of the support upper surface from one side of a circumference of the support upper surface toward the inside of the support upper surface; and
a mobile transport robot configured to transport the pedestal on which the plurality of types of loads are provided, by connecting the docking groove to a docking block provided on an upper surface thereof,
wherein the docking block is configured to be raised or lowered,
a terminal at least partially protrudes from an upper surface of the docking block, the terminal being a communication terminal or a power terminal,
a recessed groove is formed in the upper surface of the docking block,
an elastic member is provided in the recessed groove,
at least a portion of the terminal is inserted into the recessed groove so that one end of the terminal comes into contact with one end of the elastic member,
a planar shape of the docking block is an L-shape,
four docking blocks are provided on the upper surface of the mobile transport robot and are spaced apart from each other,
two docking blocks among the four docking blocks each comprise two power terminals and one communication terminal,
a planar shape of the docking groove is an L-shape,
four docking grooves are formed in the lower surface of the pedestal to be spaced apart from each other, and
the docking groove in the lower surface of the pedestal is complementarily connected to the docking block provided on an upper surface of the mobile transport robot, so that the load is electrically connected to the mobile transport robot.
